(19) United States
(12) Patent Application Publication
(10) Pub. No.: US 2010/0084728 A1
(43) Pub. Date: Apr. 8, 2010

(54) SOLID-STATE IMAGING DEVICE AND METHOD FOR MANUFACTURING THE SAME

(75) Inventor: Tohru YAMADA, Tokyo (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/573,276

(22) Filed: Oct. 5, 2009

(30) Foreign Application Priority Data
Oct. 8, 2008 (JP) 2008-262131

(51) Int. Cl. H01L 31/0232; H01L 31/18

(52) U.S. Cl. 257/432; 438/70; 257/E31.127; 257/E31.122

(57) ABSTRACT

A solid-state imaging device according to the present invention includes light-receiving units formed on a surface in a substrate, a photo-shield film formed above the substrate and having openings above the light-receiving units, a light-transmissive insulating film formed above the photo-shield film and in the openings in the photo-shield film, downwardly convex in-layer lenses made of a material having a refractive index different from that of the light-transmissive insulating film and formed above the light-transmissive insulating film, an OCCF formed above the in-layer lenses and having a first filter and a second filter which are positioned above different ones of the light-receiving units and transmit lights of different wavelengths, and OCLs formed above the in-layer lenses. The width of the openings in the photo-shield film and the curvature of the in-layer lenses provided under the first filter and those under the second filter are different from each other, respectively.

### BACKGROUND OF THE INVENTION

(1) Field of the Invention

The present invention relates to a solid-state imaging device which includes a photo-shield film having openings formed above light-receiving units and in-layer lenses which are convex downward and embedded in an interlayer insulating film between the to photo-shield film with the openings and on-chip lenses.

(2) Description of the Related Art

Currently, there are eager demands for CCD solid-state imaging devices having chips of smaller sizes and more pixels. However, providing a chip of a smaller size without changing the current size of pixels merely decreases the number of pixels, resulting in reduced resolution. On the other hand, providing a chip having more pixels without changing the current size of the pixels makes the size of the chip larger and causes increase in production costs or loss in yield of chips. Accordingly, reduction in the size of pixels is necessary for providing chips of smaller sizes or more pixels. With pixels of a reduced size, a smaller CCD solid-state imaging device can be provided which has resolution as high as ever or resolution is improved without changing the size of chips.

However, when the size of pixels is reduced, the amount of incident light to the pixels decreases, which causes a problem of deterioration in sensitivity characteristic of a light-receiving unit of each of the pixels. Although the sensitivity characteristic may be maintained by enhancing conversion efficiency of an output circuit, at the same time an S/N ratio of an image signal outputted from the CCD solid-state imaging device deteriorates because noise content is also amplified. In other words, in order to prevent such deterioration in the S/N ratio, sensitivity characteristic of pixels of a reduced size needs to be maintained not only by enhancing conversion efficiency of an output circuit but also by improving light collection efficiency of each of the pixels as much as possible.

In view of this, there is a technique for improving efficiency of light collection to light-receiving units using on-chip lenses (OCLs) provided above color filters above light-receiving units. However, improvement of light collection efficiency only using on-chip lenses with a CCD solid-state imaging device having pixels of, for example, 4 μm×4 μm or smaller is reaching a limit. In order to overcome the limit, there is a known technique for a CCD solid-state imaging device having light collection efficiency further improved by forming additional in-layer lenses made of a light-transmissive insulation film in an interlayer insulating film between on-chip lenses and light-receiving units (see Patent Reference 1, for example).

FIG. 16 is a sectional view (of approximately three pixels) which schematically shows a structure of a CCD solid-state imaging device conventional in the art.

As shown in FIG. 16, spaced light-receiving units 2 are formed in a surface region within a silicon substrate or a p-type well (hereinafter referred to as a substrate 1) formed in a silicon substrate. The light-receiving units 2, which may be composed of, for example, n-type impurity regions, generate signal charges by photoelectric conversion in areas centered around pn-junctions with the substrate 1, and accumulate the signal charges for a period of time. A column CCD unit 3, which is mainly composed of an n-type impurity region, is formed in each of the spaces between the light-receiving units 2 at a distance from the light-receiving units 2 on the both sides thereof. Although not shown in FIG. 16, a p-type impurity region is formed between each of the light-receiving units 2 and corresponding one of column CCD units 3 adjacent to the light-receiving unit 2. The p-type impurity region provides a variable potential barrier at a readout gate portion. In addition, a high-concentration p-type impurity region is formed as a channel stopper between the light-receiving unit 2 and the other corresponding one of column CCD units 3 adjacent to the light-receiving unit 2. The high-concentration p-type impurity region penetrates deeply into the substrate 1.

Insulating film 4a made of materials such as silicon oxide is formed on the substrate 1. Column transfer electrodes 5 made of materials such as polysilicon are formed on the insulating films 4a above the column CCD units 3. The signal charges obtained by photoelectric conversion in the light-receiving units 2 are read out via the readout gate portions into the corresponding one of column CCD units 3 adjacent to the light-receiving unit 2. The read-out signal charges are sequentially transferred in predetermined directions in the column CCD unit 3 by driving the column transfer electrodes 5 using column transfer clock signals of four phases, for example. The signal charges provided as signal charges of respective lines to a row CCD unit, which is not shown, are transferred in the row CCD unit according to clock signals of two phases, for example, and then outputted as image signals to the outside of the device.

Insulating films 4b made of materials such as silicon oxide are formed on the column transfer electrodes 5. In addition, a photo-shield film 6 made of high-melting point metal such as tungsten (W) is formed on the insulating films 4b. The photo-shield film 6 has openings 6a which are located above the light-receiving unit 2 and formed to have an identical width for all the pixels. Circumferences of the openings 6a reach the slightly inward side of the edge of the corresponding column transfer electrodes 5. This improves light shielding effect of the photo-shield film 6 to the column CCD unit 3 in order to reduce smears.

A first light-transmissive insulating film 7 made of borophosphosilicate glass (BPSG) is formed over the photo-shield films 6 and the openings 6a so as to cover them. On the first light-transmissive insulating film 7, a second light-transmissive insulating film 8 is formed in contact with the first light-transmissive insulating film 7. The second light-transmissive insulating film 8 is formed by a plasma CVD method and made of a material having a higher refractive index than the first light-transmissive insulating film 7, such as silicon nitride (P—SiN). In the undersurface of the second light-transmissive insulating film 8, curved portions which are convex downward (downwardly convex portions) 7c, 7b, and 7a are formed so as to reflect the stepwise shape of the vertical transfer electrodes 5 and the photo-shield films 6 which form a base of the second light-transmissive insulating film 8. In the solid-state imaging device shown in FIG. 16, the downwardly convex portions 7a, 7b, and 7c are formed corresponding to a pixel into which red (R) light enters (R pixel), a pixel into which green (G) light enters (G pixel), and a pixel into which blue (B) light enters (B pixel), respectively. The downwardly convex portions are set to have greater depths in order of 7c, 7b, and 7a. Thus, the curvature of the downwardly convex portion 7a is the largest, followed by the curvature of the downwardly convex portion 7b, and the curvature of the downwardly convex portion 7c. The second light-transmissive insulating film 8 is planarized on the upper surface thereof and forms in-layer lenses which are convex downward.

On-chip color filters (OCCFs) 9 are disposed on the planarized surface of the second light-transmissive insulating film 8. The OCCFs 9 are provided with a primary color system. Light-transmissive regions are partitioned with boundary regions 9a and colored red (R), green (G), or blue (B). On-chip lenses (OCLs) 10 which are made of a light-transmissive material are disposed on the OCCFs 9.

In a solid-state imaging device having the structure described above, light received on lens surfaces (convex curves) of the OCLs 10 is collected, and then further collected by the aforementioned in-layer lenses to enter the light-receiving units 2. The OCLs 10 are formed on a surface of the CCD solid-state imaging device so as to provide spaces which are ineffective regions as small as possible and allow light above the photo-shield films 6 to enter the light-receiving units 2 for better efficiency, thus sensitivity of the pixels are improved.

A method for manufacturing the CCD solid-state imaging device shown in FIG. 16 is hereinafter described with reference to FIGS. 17 to 20. FIGS. 17 to 20 are a sectional view (of approximately three pixels) schematically showing a structure of a CCD solid-state imaging device conventional in the art.

First, as shown in FIG. 17, impurity regions are formed in a silicon substrate according to a conventional method. Specifically, p-type wells and the like are formed in a surface region of a prepared silicon substrate by ion implantation of p-type impurities as needed basis, and then channel stoppers are formed by ion implantation of high-concentration p-type impurities. Next, a light-receiving unit 2 is formed on one side of each of the channel stoppers by ion implantation of n-type impurities under a predetermined condition while a column CCD unit 3 is formed on the other side of each of the channel stoppers by ion implantation of n-type impurities under a predetermined condition. In addition, readout gate portions are formed between the column CCD units 3 and the light-receiving units 2 by ion implantation of p-type impurities under a predetermined condition. Subsequently, an insulating film 4a, which is made of, for example, a silicon oxide film, is formed, using a thermal oxidation method or a chemical vapor deposition (CVD) method, on the surface of the silicon substrate on which the impurity regions are formed. Polysilicon having conductance increased by adding impurities is deposited on the insulating layer 4a using the CVD method, and patterning is then applied to the polysilicon to form a column transfer electrodes 5. An insulating layer 4, which is made of, for example, silicon oxide, is formed so as to cover the formed column transfer electrodes 5. In addition, a film of high-melting point metal such as tungsten (W) is deposited on the insulating layers 4b using the CVD method, and pattering is then applied to the film of high-melting point metal so as to provide with an opening above each of the light-receiving units 2. Subsequently, a first light-transmissive insulating film 7d made of BPSG is formed on the photo-shield film 6 and openings 6a therein. The formed BPSG film has concave portions 17a′, 17b′, and 17c′, which are identical in size, above the light-receiving units 2. These concave portions are formed to reflect a stepwise shape formed by the underlying column transfer electrodes 5 and the photo-shield film 6.

Subsequently, as shown in FIG. 18, a resist pattern R which opens at a region (hereinafter referred to a G region) centered around one of the light-receiving unit 2 corresponding to a pixel which receives green light is formed on the first light-transmissive insulating film 7d. Then, the resist pattern R is used as a mask for ion implantation of boron ions (B⁺) or phosphorus ions (P⁺) at a predetermined concentration into the first light-transmissive insulating film 7d. With this, boron or phosphorus is added to the G region of the first light-transmissive insulating film 7d at a predetermined concentration.

Subsequently, the resist pattern R is removed, and then a resist pattern R which opens at an area (hereinafter referred to a B region) centered around another one of the light-receiving unit 2 corresponding to a pixel which receives blue light is formed on the first light-transmissive insulating film 7d as shown in FIG. 19. Then, the resist pattern R is used as a mask for ion implantation of boron ions (B⁺) or phosphorus ions (P⁺) at a predetermined concentration into the first light-transmissive insulating film 7d. With this, boron or phosphorus is added to the B region of the first light-transmissive insulating film 7d at a predetermined concentration. The concentration of the impurities for this ion implantation is set to higher than the concentration of the impurities for the ion implantation into the G region.

Subsequently, the resist pattern R is removed, and then the first light-transmissive insulating film 7d is heated to 900 to 1000° C. for reflow. Then, the PSG or the BPSG included in the first light-transmissive insulating film 7d is softened by heat and rounded in corners thereof, so that the first light-transmissive insulating film 7d is deformed to partly fill the concave portions on the surface of the first light-transmissive insulating film 7d as shown in FIG. 20. The PSG or the BPSG is reflowed more as the concentration of the impurities is higher. Thus, the concave portion 17c′ of the B region, which has the highest concentration of impurities, is reflowed most and, as a result, a concave portion 17c having a shallow curve of small curvature is formed. The concave portion 17b′ of the G region, which has the second highest impurities, forms a concave portion 17b having intermediate depth and curvature. The concave portion 17a′ of a region (an R region) which has no additional impurities forms the deepest concave portion 17a of the largest curvature. Subsequently, silicon nitride is deposited on the formed first light-transmissive insulating layer 7 using the plasma CVD method, and then resist is applied to the surface of the silicon nitride. After planarization, etchback is performed under a condition where etching selectivity ratio between the resist and the silicon nitride is 1. With this, a second light-transmissive layer 8 which has a planarized surface is formed as shown in FIG. 16.

Subsequently, OCCFs 9 are formed on the planarized surface of the second light-transmissive insulating layer 8 using, for example, a dyeing method.

Finally, light-transmissive resin such as negative photosensitive resin is thickly deposited on the OCCFs 9 and then formed to be OCLs 10 by etching using a rounded resist pattern as a mask

FIG. 21 shows light collection in the case where light vertical to light-receiving surfaces (vertical light) enters the CCD solid-state imaging device shown in FIG. 16. The CCD solid-state imaging device has 2 μm×2 μm or larger pixels and 700 nm or wider openings 6a (for example, 900 nm) in the photo-shield film 6 for all the pixels. FIG. 22 shows a spectral sensitivity characteristic of the CCD solid-state imaging device shown in FIG. 16. FIG. 22 indicates that the CCD solid-state imaging device shown in FIG. 16 has sensitivity to red light within a wavelength range from approximately 580 to 680 nm with a peak at 610 nm. Similarly, the CCD solid-state imaging device has sensitivity to green light within a wavelength range from approximately 480 to 580 nm and a peak at 530 nm and sensitivity to blue light within a wavelength range from approximately 400 to 480 nm and a peak at 450 nm.

In the CCD solid-state imaging device shown in FIG. 16, the width (a in FIG. 21) of the opening 6a in the photo-shield film 6 is larger than the wavelength of the red light. Focal distances of in-layer lenses are determined by curvatures of the downwardly convex portions 7a, 7b, and 7c and the curvatures are optimized for each of the pixels of R, B, and G. This equalizes light collectivities of the pixels of R, G, and B for light which has passed through the OCCF 9. In other words, focal positions of vertical light which enters the pixels of R, G, and B may be aligned to the approximate center of the light-receiving unit 2. Furthermore, entering of light into the column CCD units 3, which causes smears, is effectively prevented because the pixel size of 2 μm×2 μm or larger is large enough and a sufficient distance is secured from the edge of the openings 6a in the photo-shield film 6 to the column CCD units 3. Accordingly, an effect of effective reduction of smears is observed especially with the CCD solid-state imaging device which has 2 μm×2 μm or larger pixels and 700 nm or wider openings 6a in the photo-shield film 6.

[Patent Reference 1] Japanese Unexamined Patent Application Publication No. 2002-151670

### SUMMARY OF THE INVENTION

In such a conventional CCD solid-state imaging device, diffraction affects light, especially red light having a longer wavelength, at openings in a photo-shield film when pixels are smaller than 2 μm×2 μm and the width of the openings in the photo-shield film is smaller than 700 nm. As a result, a problem arises that it is difficult to effectively prevent light from entering column CCD units only by optimizing curvature of in-layer lenses.

FIG. 23 shows light collection in the case where vertical lights of three primary colors, R, G, and B, enter light-receiving surfaces of a CCD solid-state imaging device. The CCD solid-state imaging device has 1.5 μm×1.5 μm pixels and 620 nm-wide (a in FIG. 23) openings in the photo-shield film 6. As shown in FIG. 23, wavelengths of red light (approximately 580 to 680 nm) and a width of an opening 6a (620 nm) in a photo-shield film 6 are approximate to each other in the R pixel; thus influence of diffusion of incident light in a substrate 1 due to diffraction at the opening 6a in the photo-shield film 6 is dominant over influence of light collection of an in-layer lens. As a result, the amount of red incident light into the column CCD unit 3 increases so much that smears cannot be reduced only by optimizing curvature of the in-layer lens.

In the B pixel, wavelengths of blue light (approximately 400 to 480 nm) are enough larger than a width of an opening 6a (620 nm) in the photo-shield film 6; thus influence of light collection of the in-layer lens is dominant over influence of diffraction at the opening 6a in the photo-shield film 6. As a result, light is collected by the in-layer lens in the B pixel with little influence of the diffraction at the opening 6a in the photo-shield film 6. However, the light collected by the in-layer lens directly enters the column CCD unit 3 because the distance from the edge of the opening 6a in the photo-shield film 6 to a column CCD unit 3 is shortened due to reduction in the pixel size. Thus, it is still difficult to reduce smears only by optimizing curvature of the in-layer lens.

On the other hand, in the G pixel, the difference between wavelengths of green light (approximately 480 to 580 nm) and a width of an opening 6a (620 nm) in the photo-shield film 6 is so small that influence of diffraction at an opening 6a in the photo-shield film 6 and influence of light collection of the in-layer lens are nearly equal. As a result, light collected by an in-layer lens in the G pixel does not enter the column CCD unit 3 and smears are reduced.

Thus less smears occur in the R pixel but more occur in the B pixel in the conventional CCD solid-state imaging device when openings in the photo-shield film are formed to have a larger width. In contrast, less smears occur in the B pixel but more occur in the R pixel when the opening in the photo-shield film is formed to have a smaller width. Thus, there is a problem that smear cannot be reduced both in the R pixel and the B pixel at the same time. This is obvious from FIG. 24 which shows relationship between the width of openings in the photo-shield film and smear output. Specifically, it is obvious because widths of openings, which is determined by influence of diffraction at openings in a photo-shield film and influence of light collection by an in-layer lens and minimizes influence of smears are different among pixels of the colors R, G, and B. It is noted that circles in FIG. 24 indicates widths of openings for pixels of each colors in the conventional CCD solid-state imaging device.

Such trade-off of smear reduction among pixels of each of the colors is not a particular problem when the size of the pixels is large enough, a sufficient distance between edges of the respective openings in the photo-shield film and the corresponding column CCD units is secured, and the width of the openings in the photo-shield film is sufficiently larger than the wavelength of incident light. However, this emerges as a noticeable problem when the size of the pixels is reduced, the distance between the edges of the respective openings in the photo-shield film and the corresponding column CCD units is shortened, and the width of the opening in the photo-shield film made as small as the largest wavelength of incident light with reduction in the size of chips and increase in the number of pixels. Since reduction in the size of pixels is advanced in recently years further than before, it is highly desirable to solve this problem.

Furthermore, in a conventional method for manufacturing a CCD solid-state imaging device, BPSG is deposited on a photo-shield film and openings therein, an opening is next formed in resist, and ion implantation of boron and phosphorus at a predetermined concentration is then performed in order to form an in-layer lens having an intermediate curvature in a G pixel. Similarly, to form an in-layer lens in a B pixel, another opening is formed in resist, and ion implantation of boron and phosphorus at a concentration higher than for the G pixel is then performed. After this, the BPSG is heated to 900 to 1000° C. for reflow, so that in-layer lenses, which have less acute curvatures in order of R, G, and B, are formed. This manufacturing method has three problems. A first problem is that it requires longer manufacturing lead time and higher costs because this method includes two resist forming processes and an ion implantation process which are additionally required for varying curvatures of in-layer lenses of the pixels of the colors of R, G, and B. Especially in these years when price-reduction of compact digital still cameras is remarkable, longer manufacturing lead time and higher costs have an important adverse effect on cost reduction of CCD solid-state imaging devices. A second problem is that it is very difficult to control, in reflowing, shapes of downwardly convex portions of G and B pixels and minimize variations between the shapes because boron or phosphorus, which is impurities to be introduced in BPSG by ion plantation, cannot be added evenly in the BPSG film because impurity profiles of boron and phosphorus in the BPSG film have their peaks. A third problem is that saturating amount of charge at the light-receiving unit decreases when boron is implanted to penetrate through the BPSG in the light-receiving unit and that introduction of phosphorus into the light-receiving unit causes deterioration in image quality due to white defect. This is because part of implantation species is likely to penetrate through the BPSG and be implanted in the light-receiving unit in ion implantation of boron and phosphorus.

The present invention, conceived to solve these problems, has an object of providing a solid-state imaging device in which unnecessary charges which is generated in a charge transfer unit and causes a smear are reduced even when pixels are reduced in size, and an object of providing a method for manufacturing the solid-state imaging device.

In order to achieve the above-mentioned object, a solid-state imaging device according to the present invention includes: light-receiving units formed on a surface in a substrate; a photo-shield film formed above the substrate and having an opening above each of the light-receiving units; a light-transmissive insulating film formed above the photo-shield film and in the openings in the photo-shield film; in-layer lenses each of which is downwardly convex, made of a material having a refractive index different from a refractive index of the light-transmissive insulating film, and formed above the light-transmissive insulating film; a color filter formed above the in-layer lenses and including a first filter and a second filter which are positioned above different light-receiving units among the light-receiving units, each of the first filter and the second filter transmitting light, and a wavelength of the light which the first filter transmits and a wavelength of the light which the second filter transmits being different from each other; and an on-chip lens formed above each of the in-layer lenses, wherein a width of the opening provided in the photo-shield film and under the first filter is different from a width of the opening provided in the photo-shield film and under the second filter, and a curvature of the in-layer lenses provided under the first filter is different from a curvature of the in-layer lenses provided under the second filter.

With this, light collection by the in-layer lens and diffraction at the opening in the photo-shield film are balanced in each of the pixels in accordance with wavelengths of lights to be converted into electric charges, so that diffusion of incident light in the light-receiving unit is reduced for pixels of each of the colors. As a result, a solid-state imaging device is achieved that reduces generation of unnecessary electric charges in a charge transfer unit, which causes smears, even when the size of pixels is reduced.

Here, the in-layer lens may further have an upwardly convex lens curve.

With this, light entering through the edge portion of the on-chip lens is effectively led to the openings in the photo-shield film; thus the solid-state imaging device is achieved with high sensitivity.

Furthermore, the present invention may be embodied as a method for manufacturing a solid-state imaging device, the method including: forming a photo-shield film above a substrate on which light-receiving units are formed; forming openings having different widths in positions above the light-receiving units in the photo-shield film; forming a first light-transmissive insulating film above the photo-shield film and in the openings in the photo-shield film; forming above the first light-transmissive insulating film a first in-layer lens which is downwardly convex and made of a second light-transmissive insulating film having a refractive index different from a refractive index of the first light-transmissive insulating film; and forming a color filter and on-chip lenses above the in-layer lenses.

With this, a solid-state imaging device is achieved that reduces generation of unnecessary electric charges in a charge transfer unit, which causes smears, even when the size of pixels is reduced. In addition, in-layer lenses of different curvatures are formed by adjusting thickness of the photo-shield film and width of the openings, so that increase in a manufacturing process is avoided; thus a less-costly solid-sate imaging device is achieved through a simple process.

In a solid-state imaging device according to the present invention, width of the openings in the photo-shield film and curvature of downwardly convex lenses are optimized according to each wavelength of incident light (or each pixel). With this, oblique light due to diffraction of incident light at the openings and oblique light due to light collection by the in-layer lens are balanced. As a result, diffusion of incident light in the light-receiving units of pixels of each of the colors R, G, and, B can be reduced, so that light which enters the charge transfer unit is reduced. Thus smears are effectively reduced especially for minute pixels of 2 μm×2 μm or smaller.

Furthermore, the method for manufacturing the solid-state imaging device according to the present invention, which requires no additional process such as ion plantation in order to optimize curvature of downwardly convex in-layer lenses, allows optimization of curvature of in-layer lenses with good precision only by adjusting thickness of the photo-shield film and width of the openings. As a result, cost is significantly reduced, variation in shapes is reduced, and deterioration in image quality such as white defect is avoided.

### FURTHER INFORMATION ABOUT TECHNICAL BACKGROUND TO THIS APPLICATION

The disclosure of Japanese Patent Application No. 2008-262131 filed on Oct. 8, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows an overall configuration of a CCD solid-state imaging device according to a first embodiment of the present invention.

FIG. 2 is a sectional view which schematically shows a structure of the CCD solid-state imaging device according to the first embodiment.

FIG. 3 is a sectional view which shows a method for manufacturing the CCD solid-state imaging device according to the first embodiment.

FIG. 4 is a sectional view which shows the method for manufacturing the CCD solid-state imaging device according to the first embodiment.

FIG. 5 is a sectional view which shows light collection in the case where light enters vertically to light-receiving surfaces of the CCD solid-state imaging device.

FIG. 6 shows dependency of smears on widths of openings in a conventional CCD solid-state imaging device.

FIG. 7 shows dependency of smears on widths of openings in the CCD solid-state imaging device according to the first embodiment.

FIG. 8 shows dependency of sensitivity on widths of openings in the conventional CCD solid-state imaging device.

FIG. 9 shows dependency of sensitivity on widths of openings in the CCD solid-state imaging device according to the first embodiment.

FIG. 10 is a sectional view which schematically shows a structure of the CCD solid-state imaging device according to a second embodiment of the present invention.

FIG. 11 shows dependency of sensitivity on widths of openings in the CCD solid-state imaging device according to the second embodiment and in the CCD solid-state imaging device according to the first embodiment.

FIG. 12 is a sectional view which shows a method for manufacturing the CCD solid-state imaging device according to the second embodiment.

FIG. 13 is a sectional view which shows the method for manufacturing the CCD solid-state imaging device according to the second embodiment.

FIG. 14 is a block diagram of a camera according to a third embodiment of the present invention.

FIG. 15A is a sectional view which schematically shows a variation of a structure of a CCD solid-state imaging device according to the embodiments of the present invention.

FIG. 15B shows a spectral sensitivity characteristic of the CCD solid-state imaging device.

FIG. 16 is a sectional view which schematically shows a structure of a conventional CCD solid-state imaging device.

FIG. 17 is a sectional view which shows a method for manufacturing the conventional CCD solid-state imaging device.

FIG. 18 is a sectional view which shows the method for manufacturing the conventional CCD solid-state imaging device.

FIG. 19 is a sectional view which shows the method for manufacturing the conventional CCD solid-state imaging device.

FIG. 20 is a sectional view which shows the method for manufacturing the conventional CCD solid-state imaging device.

FIG. 21 is a sectional view which shows light collection in the case where light enters vertically to light-receiving surfaces of the conventional CCD solid-state imaging device.

FIG. 22 shows a spectral sensitivity characteristic of the CCD solid-state imaging device.

FIG. 23 is a sectional view which shows light collection in the case where light enters vertically to light-receiving surfaces of the conventional CCD solid-state imaging device.

FIG. 24 shows relationship between widths of openings in the photo-shield film and smear output in the CCD solid-state imaging device.

### DESCRIPTION OF THE PREFERRED EMBODIMENTS

A CCD solid-state imaging device (CCD imager), an apparatus to manufacture the same, and a camera according to embodiments of the present invention are hereinafter described with reference to figures.

### First Embodiment

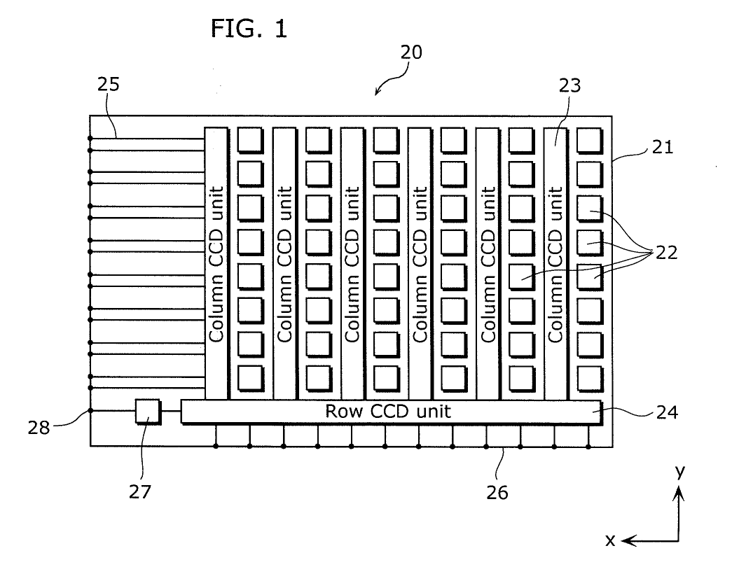

FIG. 1 shows an overall configuration of a CCD solid-state imaging device having a pixel, the size of which is smaller than 2 μm×2 μm, such as 1.5 μm×1.5 μm, according to a first embodiment.

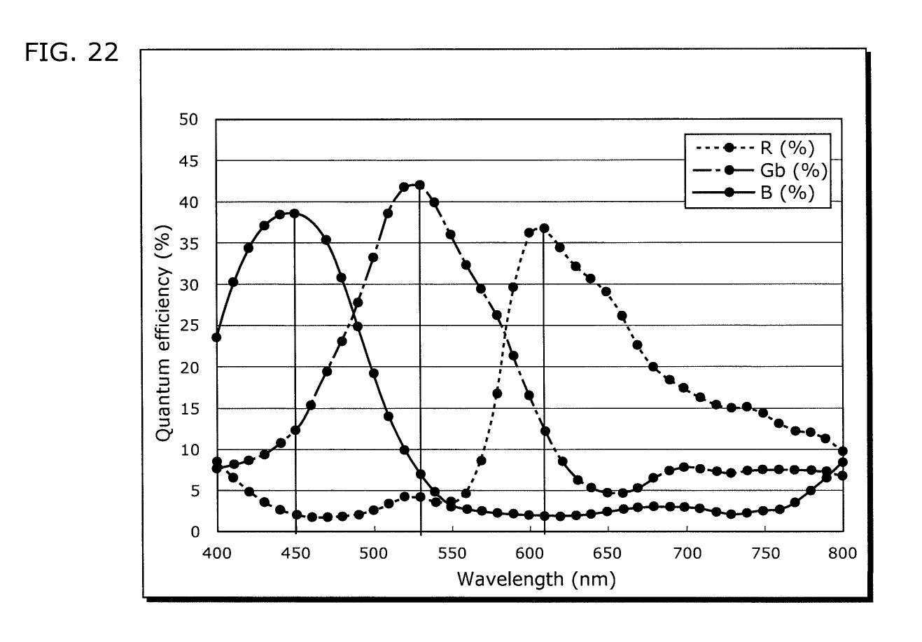

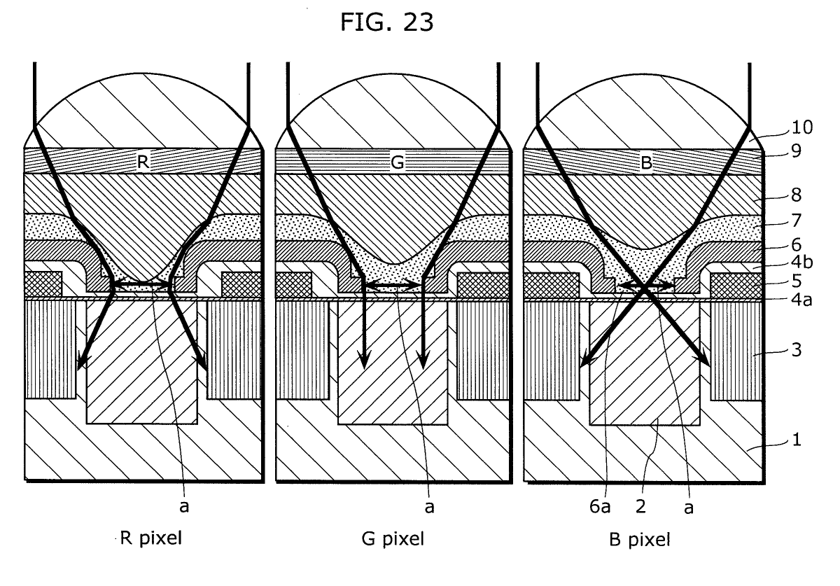

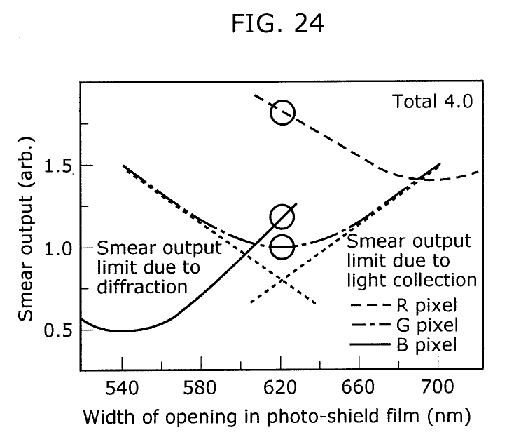

A CCD solid-state imaging device 20 according to the first embodiment has many column CCD units 23 running in a direction of column transfer (y direction in FIG. 1) and arranged in a stripe pattern on a substrate 21. A column of light-receiving units 22 of pixels are arranged in each space between the column CCD units 23 and make a column running in parallel with the column CCD units 23. Between the column of the light-receiving units 22 and one of the column CCD units 23 sandwiching the column of the light-receiving units 22 a readout gate portion (not shown) is provided for each of the pixels. Between the column of the light-receiving units 22 and the other one of the column CCD units 23 sandwiching the column of the light-receiving units 22 a channel stopper (not shown) is provided which prevents leak of signal charges generated in each of the light-receiving units 22 to the other one of the column CCD units 23. In addition, a row CCD unit 24 is disposed on the substrate 21 in a direction of row transfer (x direction in FIG. 1). Signal charges transferred by the row CCD unit 24 are provided for an amplification unit 27 connected to an output unit 28. The column CCD unit 23 and the row CCD unit 24 are driven using a column transfer clock signal and a row transfer clock signal provided via column bus line wires 25 and a row bus line wire 26, respectively. The CCD solid-state imaging device 20 has the spectral sensitivity characteristic shown in FIG. 22.

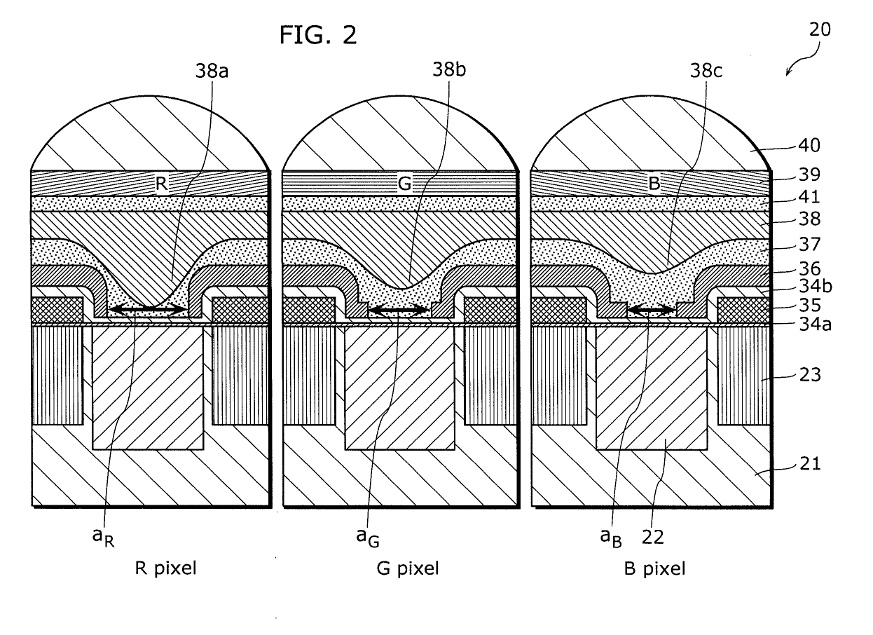

FIG. 2 is a sectional view (of approximately three pixels sectioned in a direction perpendicular to the column transfer direction) which schematically shows a structure of the CCD solid-state imaging device 20 according to the first embodiment.

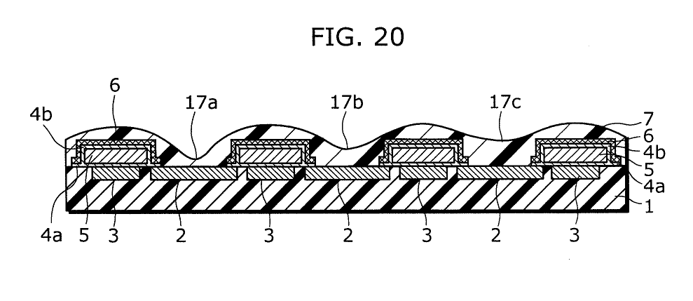

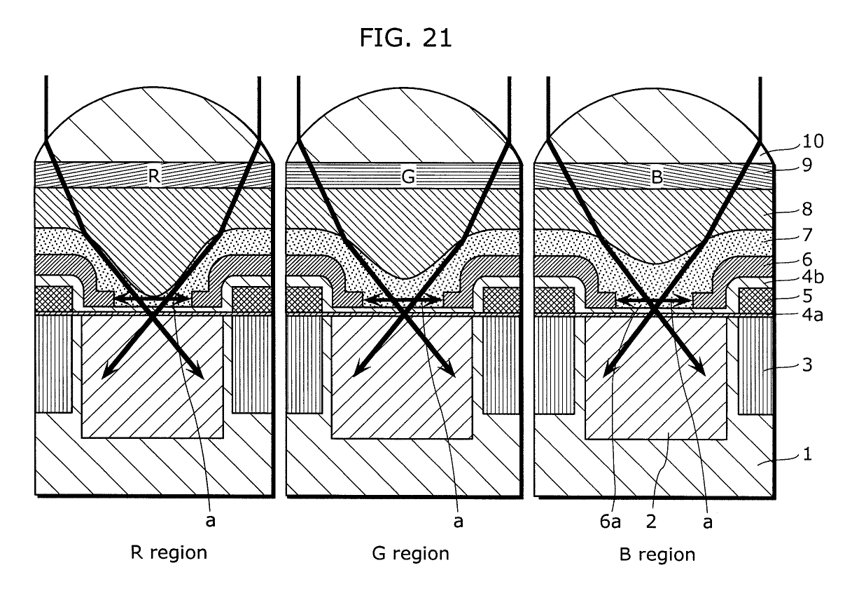

On a silicon substrate or a surface region of a p-type well (hereinafter referred to as a substrate 21) formed in the silicon substrate, light-receiving units 22 are formed with spaces therebetween. The light-receiving units 22, which may be n-type impurity regions, perform photoelectric conversion to generate signal charges, and accumulate the signal charges for a predetermined period of time. A column CCD unit 23, which includes in large part an n-type impurity region, is formed between the light-receiving units 22 at a predetermined distance from the light-receiving units 22 sandwiching the column CCD unit 23. Although not shown in FIG. 20, a p-type impurity region is formed between each of the light-receiving units 22 and corresponding one of column CCD units 2 adjacent to the light-receiving unit 22. The p-type impurity region provides a variable potential barrier in a readout gate portion. In addition, a high-concentration p-type impurity region is formed as a channel stopper between each of the light-receiving unit 22 and the other corresponding one of the column CCD units 23 adjacent to the light-receiving unit 22.

A gate oxide film 34a is formed on a surface of the substrate 21. Column transfer electrodes 35 made of polysilicon, for example, are formed via the gate oxide films 34a above the column CCD units 23. Signal charges obtained by photoelectric conversion in the light-receiving unit 22 is read out into the column CCD unit 23 through the readout gate portion, and are then transferred in predetermined directions in the column CCD unit 23 by driving a column transfer electrode 35 using column transfer clock signals of, for example, four phases. The signal charges provided as signal charges of respective lines to a row CCD unit 24 are transferred in the row CCD unit 24 to the amplification unit 27 according to row transfer clock signals of two phases, for example, and then outputted as image signals to the outside of the device.

An interlayer oxide film 34b made of silicon oxide, for example, is formed on the column transfer electrodes 35. In addition, a photo-shield film 36 made of high-melting point metal, such as tungsten (W), is formed on the interlayer oxide film 34b above the substrate 21. The photo-shield film 36 has openings above the light-receiving units 22. Among the widths of the openings, the width (a_{R} in FIG. 2) of the opening of an R pixel is the largest, followed by the width (a_{G} in FIG. 2) of the opening of a G pixel, and the width (a_{B} in FIG. 2) of the opening of a B pixel is the smallest. Reasons for this are described later. Circumferences of the openings reach the slightly inward side of the edge of the corresponding column transfer electrodes 35. This improves light shielding effect of the photo-shield film 36 to the column CCD unit 23 in order to reduce smears.

Here, the width of the opening in the photo-shield film 36 corresponding to an R filter film of an on-chip color filter (OCCF) 39 for which a light transmission region is red (R) is equal to or larger than a wavelength of red light which the R filter film transmits in a light-transmissive insulating film 37. The width of the opening in the photo-shield film 36 corresponding to a G filter film for which a light transmission region is green (G) is equal to or larger than a wavelength of green light which the G filter film transmits in the light-transmissive insulating film 37. The width of the opening in the photo-shield film 36 corresponding to a B filter film for which a light transmission region is blue (B) is equal to or larger than a wavelength of blue light which the B filter film transmits in the light-transmissive insulating film 37. In this case, the width of the opening in the photo-shield film 36 is desirably larger than 1.5 times of the wavelength of corresponding light in the light-transmissive insulating film 37 because diffraction greatly influences when the width of the opening in the photo-shield film 36 is smaller than 1.5 times of the wavelength of corresponding light in the light-transmissive insulating film 37.

The width of the opening in the photo-shield film 36 corresponding to the R filter film of is larger than the width of the opening in the photo-shield film 36 corresponding to the G filter film. The width of the opening in the photo-shield film 36 corresponding to the G filter film is larger than the width of the opening in the photo-shield film 36 corresponding to the B filter film.

It is necessary that the photo-shield film 36 fully covers the column CCD unit 23 of each of the pixels in order to prevent smears caused by direct entering of light into the column CCD unit 23. Thus, the widths of the openings in the photo-shield film 36 are not made larger than the size of the pixels (1.5 μm×1.5 μm) and have an upper limit of a value obtained by subtracting the width of the column CCD unit 23 (0.6 μm) from the size of the pixels.

In the case where the light-transmissive insulating film 37 is made of BPSG, the light-transmissive insulating film 37 has a refractive index of approximately 1.5; thus the wavelength of the red light in the light-transmissive insulating film 37 is a value obtained by dividing the value of the wavelength (approximately 580 to 680 nm) of red light in vacuum by 1.5. Similarly, the wavelength of the green light in the light-transmissive insulating film 37 is a value obtained by dividing the value of the wavelength (approximately 480 to 580 nm) of green light in vacuum by 1.5. The wavelength of the blue light in the light-transmissive insulating film 37 is a value obtained by dividing the value of the wavelength (approximately 400 to 480 nm) of blue light in vacuum by 1.5. Accordingly, to satisfy the conditions of the widths of the opening described above, the opening of the R pixel has a width (a_{R}) of, for example, 700 nm, the opening of the G pixel has a width (a_{G}) of, for example, 620 nm, and the opening of the B pixel has a width (a_{B}) of, for example, 540 nm.

On the photo-shield film 36 and in the openings therein, the light-transmissive insulating film 37 which is made of BPSG, for example, is formed. Concave portions are formed on the upper surface of the light-transmissive insulating film 37. The concave portions have shapes which reflect shapes of steps formed with the underlying column transfer electrode 35, the photo-shield film 36, and openings therein, so that the concave portions have different depths for pixels of B, G, and R, which become deeper in this order.

On the light-transmissive insulating film 37, an in-layer lens 38, which is downwardly convex, is formed so as to fill the concave portion in the light-transmissive insulating film 37. The in-layer lens 38 is made of a material having a different refractive index from the light-transmissive insulating film 37, such as silicon nitride SiN formed by a plasma CVD method. The upper surface of the in-layer lens 38 is planarized. In the CCD solid-state imaging device 20, the R pixel has openings of the largest width in the photo-shield film 36, followed by the G pixel, and then B pixel, and the downwardly convex portions (downwardly convex portions) 38a, 38b, and 38c of the in-layer lens 38 have shapes which reflect shapes of steps due to difference in the widths of the openings, so that the downwardly convex portions necessarily have different depths. Specifically, the curvature of the downwardly convex portion 38a which corresponds to the R filter film is larger than the curvature of the downwardly convex portion 38b which corresponds to the G filter film. The curvature of the downwardly convex portion 38b which corresponds to the G filter film is larger than the curvature of the downwardly convex portion 38c which corresponds to the B filter film. The downwardly convex portions have greater curvatures in order of 38c, 38b, and 38a.

On the in-layer lens 38, a planarizing film 41 is formed, and an OCCF 39 is disposed thereon. The OCCF 39 includes a plurality of filter films which is placed above different light-receiving units 22 and transmits lights of different wavelengths. Specifically, the OCCF 39 is provided with color coding of primary colors and formed with an array of filter films of R, G, and B. On the OCCF 39, on-chip lenses (OCLs) 40 made of a light-transmissive material are placed. Light received on lens surfaces (convex curves) of the OCLs 40 is collected, and then further collected by the in-layer lenses 38 to enter the light-receiving unit 22. The OCLs 40 are formed on a surface of the CCD solid-state imaging device 20 so as to provide spaces which are ineffective regions as small as possible and allow light above the photo-shield film 36 to enter the light-receiving units 22 for better efficiency, thus sensitivity of the pixels are improved.

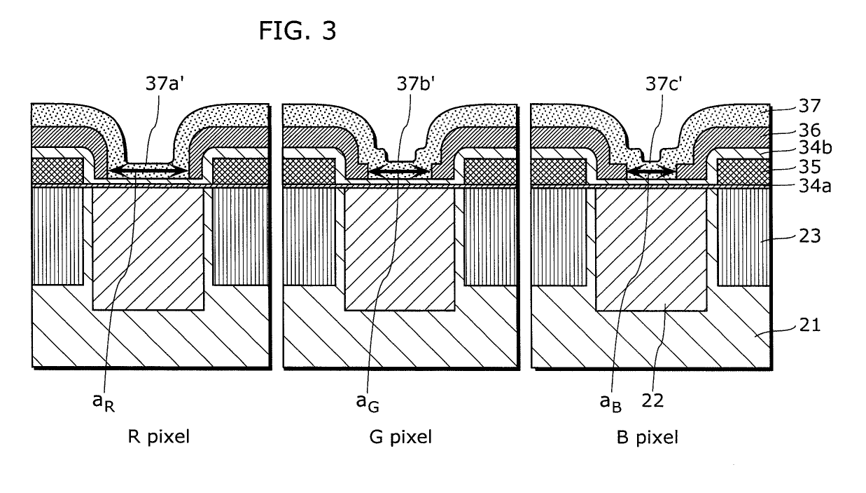

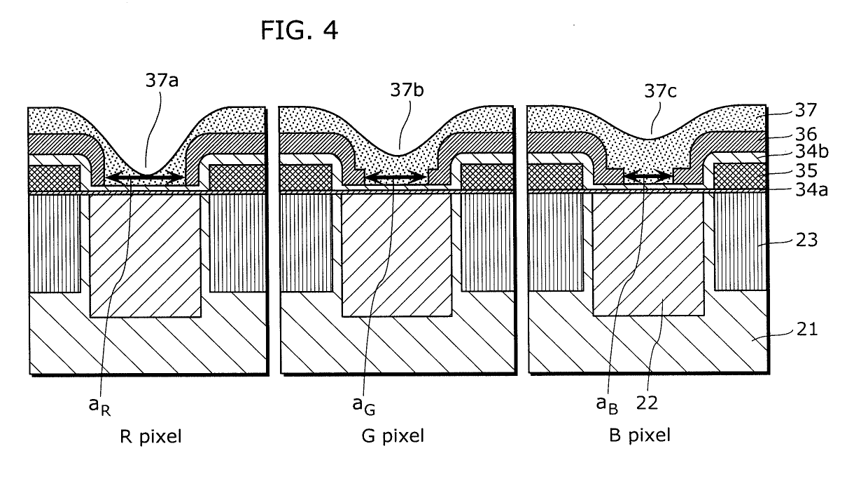

A method for manufacturing the CCD solid-state imaging device 20 according to the first embodiment is hereinafter described. FIG. 3 and FIG. 4 are sectional views (of approximately three pixels sectioned in a direction perpendicular to the column transfer direction) which schematically show structures of the CCD solid-state imaging device 20.

First, impurity regions in a silicon substrate are formed according to a known method as shown in FIG. 3. Specifically, in a surface region of a prepared silicon substrate a p-type well is formed by ion implantation of p-type impurities as needed basis, and then a channel stopper is formed by ion implantation of highly dense p-type impurities. Next, the light-receiving units 22 are formed by ion implantation of n-type impurities to one side of the channel stopper under a predetermined condition while a column CCD unit 23 is formed by ion implantation of n-type impurities to the other side of the channel stopper under a predetermined condition. In addition, a readout gate portion is formed between the column CCD unit 23 and the light-receiving unit 22 by ion implantation of p-type impurities between the column CCD unit 23 and the light-receiving unit 22 under a predetermined condition. Subsequently, a gate oxide film 34a is formed using a method such as a thermal oxidation method or a CVD method on the surface of the silicon substrate on which the impurity regions are formed. Polysilicon having conductance increased by adding impurities is deposited on the insulating layer 34a using the CVD method, and then patterning is applied to the polysilicon to form a column transfer electrode 35. An interlayer oxide film 34b made of, for example, silicon oxide is formed so as to cover the formed column transfer electrode 35. In addition, a film of high-melting point metal such as tungsten (W) is deposited using the CVD method, and then a pattering is applied to the film of high-melting point metal so as to provide the film of high-melting point metal with openings having different widths above the light-receiving units 22 in order to form the photo-shield film 36 on the substrate 21. Here, the width (a_{R} in FIG. 3) of the opening of the R pixel is formed to be the largest in the photo-shield film 36, followed by the width (a_{G} in FIG. 3) of the opening of the G pixel, and the width (a_{B} in FIG. 3) of the opening of the B pixel to be the smallest.

Next, a light-transmissive insulating film 37 made of, for example, BPSG is formed above the photo-shield film 36 and in the openings therein. The formed film of BPSG has concave portions 37a′, 37b′, and 37c′, which reflect stepwise shapes formed by the underlying column transfer electrode 35, the photo-shield film 36, and the openings therein which have different widths for pixels of respective colors. Specifically, the light-transmissive insulating film 37 has the concave portion 37a′ having the largest width for the R pixel, concave portion 37b′ having the second largest width for the G pixel, and the concave portion 37c′ having the smallest width for the B pixel in an upper surface thereof.

Next, as shown in FIG. 4, the light-transmissive insulating film 37 is reflowed by heating the light-transmissive insulating film 37 to 900 to 1000° C. Thus, the BPSG included in the light-transmissive insulating film 37 is softened by heat and rounded in corners thereof, so that the light-transmissive insulating film 37 is deformed to fill the concave portions 37a′, 37b′, and 37c′ in the surface of the light-transmissive insulating film 37. Here, the widths of the concave portions 37a′, 37b′, and 37c′ before the reflowing are reflected, so that a concave portion 37a of the R pixel is formed to be the deepest and have the largest curvature, a concave portion 37b of the G pixel to be the second deepest and have the second largest curvature, and a concave portion 37c of the B pixel to be the least deep and have the smallest curvature. It is noted that the curvatures of the concave portions 37a, 37b, and 37c of the pixels can be optimized by adjusting thickness of the photo-shield film 36. Difference in the curvatures of the concave portions 37a, 37b, and 37c of the pixels can be made smaller when the photo-shield film 36 is thinned without affecting light transmission of the photo-shield film (the thinnest limit of the thinning is 50 nm for W). On the other hand, difference in the curvatures of the concave portions 37a, 37b, and 37c of the pixels can be made larger when the photo-shield film 36 is thickened.

Next, a light-transmissive insulating film made of silicon nitride having a refractive index different from a refractive index of the light-transmissive insulating layer 37 is deposited on the formed light-transmissive insulating layer 37 using a plasma CVD method, and then resist is applied to the surface of the silicon nitride. After planarization, etchback is performed under a condition where etching selectivity ratio between the resist and the silicon nitride is one to one. This process forms an inlayer lens 38 which is convex downward under the planarized surface as shown in FIG. 1. At this time, the curvatures of the downwardly convex portions 38a, 38b, and 38c reflect the difference in the curvatures of the concave portions 37a, 37b, and 37c in the light-transmissive insulating film 37 and differ from each other.

Next, the planarizing film 41 is formed on the in-layer lens 38, and the OCCF 39 is formed on the planarizing film 41.

Finally, light-transmissive resin is thickly deposited on the OCCF 39 and then formed to be an OCL 40 by etching using a rounded resist pattern as a mask.

Next, beneficial effects produced by the CCD solid-state imaging device 20 according to the first embodiment is hereinafter described.

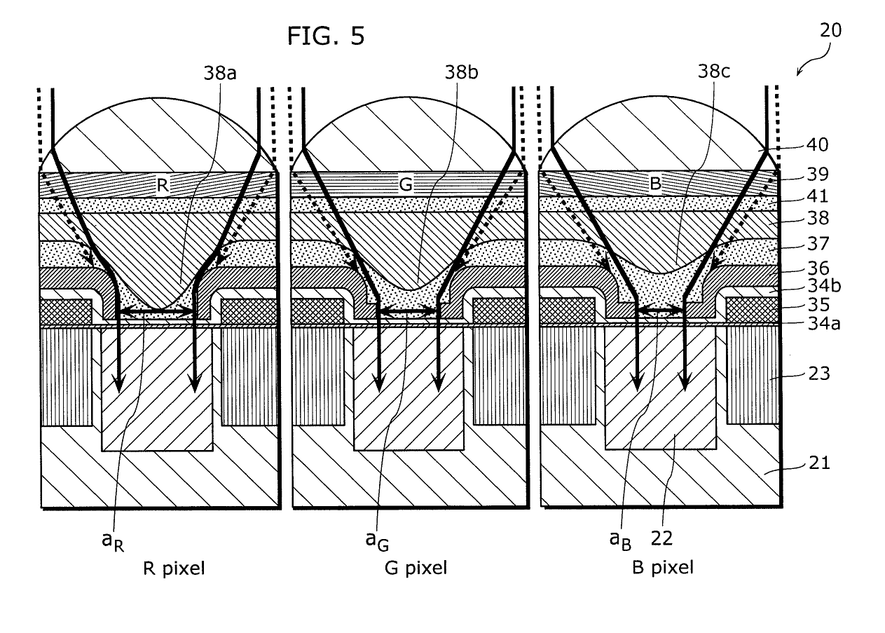

FIG. 5 is a sectional view which shows light collection in the case where light (vertical light) enters vertically to light-receiving surfaces of the CCD solid-state imaging device shown in FIG. 20.

In the CCD solid-state imaging device 20, curvatures of the downwardly convex portions 38a, 38b, and 38c of the in-layer lens 38 and widths of the openings (a_{R}, a_{G}, and a_{B} in FIG. 5) in the photo-shield film 36 are optimized for each of the R, G, and B pixels so as to allow maximum prevention of diffusion of light entering the light-receiving unit 22. Specifically, for the R pixel, the downwardly convex portion 38a is formed to be deep and have large curvature for efficient collection of red light which has the longest wavelength, and the width (a_{R} in FIG. 5) of the opening in the photo-shield film 36 is formed to be wide for reduction of diffraction at the opening. On the other hand, for the B pixel, the downwardly convex portion 38c is formed to be shallow and have small curvature for moderate collection of blue light which has the shortest wavelength, and the width (a_{B} in FIG. 5) of the opening in the photo-shield film 36 is formed to be narrow in order to cause diffraction at the opening in the photo-shield film 36 without allowing light to enter the column CCD unit 23 from the edge of the opening in the photo-shield film 36.

As described above, light collection by the in-layer lens 38 and diffraction at the opening in the photo-shield film 36 are balanced in accordance with wavelengths of lights to be converted into electric charges, so that diffusion of incident light in the light-receiving unit 22 is reduced for pixels of each of the colors of R, G, and B. As a result, occurrence of smears is minimized for pixels of any of the colors.

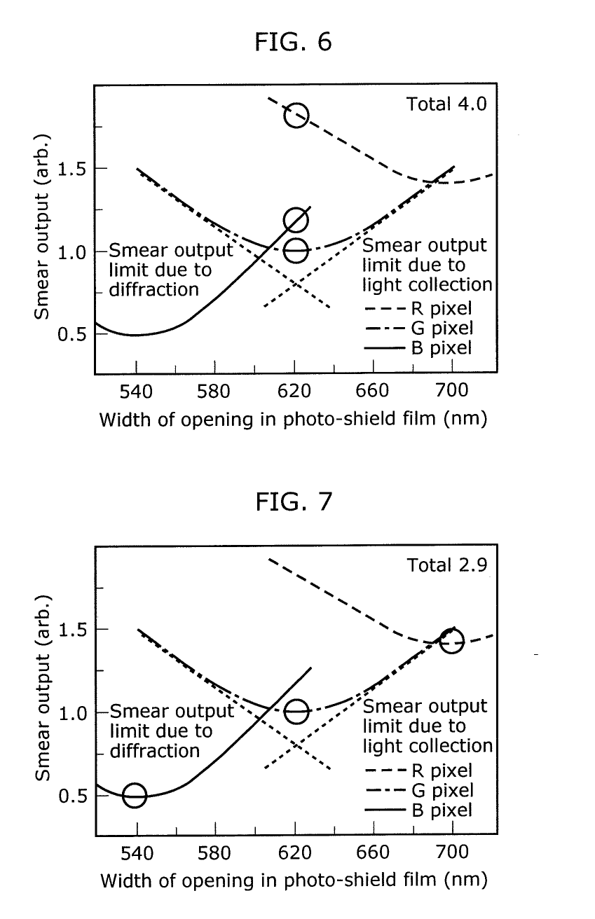

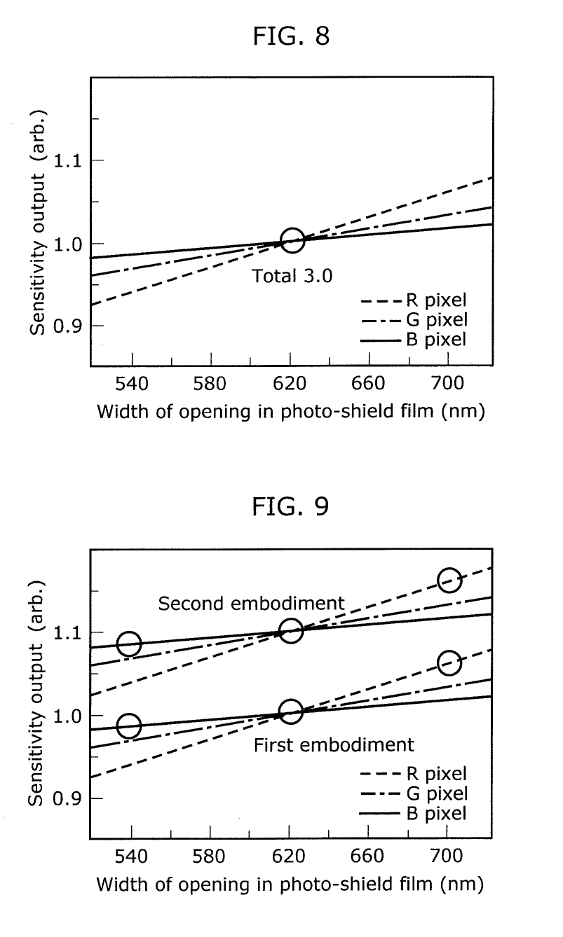

FIG. 6 and FIG. 7 show dependency of smears on widths of openings in a conventional CCD solid-state imaging device and in the CCD solid-state imaging device 20 according to the first embodiment, respectively. FIG. 8 and FIG. 9 show dependency of sensitivity on widths of openings in a conventional CCD solid-state imaging device and in the CCD solid-state imaging device 20 according to the first embodiment, respectively. Circles in FIGS. 6 to 9 indicate widths of openings for pixels of each of the colors in the CCD solid-state imaging devices.

For pixels of all of the colors, influence of oblique incident light due to diffraction at the openings is dominant in smears over influence of other incident light when the widths of the openings in the photo-shield film 36 are narrow. On the other hand, oblique incident light due to light collection by the influence of in-layer lens 38 is dominant in smears over other incident light when the widths of the openings in the photo-shield film 36 are wide. The width of openings at which diffraction and collection of light are balanced and thereby maximum reduction of smears is achieved is the largest in the R pixel, followed by the G pixel, and then the B pixel. The maximum reduction of smears in the G pixel is achieved at a width of the opening of 620 nm. When normalizing the amount of the smear at this time to 1, the amount of smear for the R pixel at the width of the opening of 620 nm is 1.8 and the amount of smear for the B pixel is 1.2 in the conventional CCD solid-state imaging device as shown in FIG. 6. The sum of the amounts of the smears for all of these colors is four (=1+1.8+1.2). On the other hand, in the CCD solid-state imaging device 20 according to the first embodiment, the width of the opening for the R pixel is set to 700 nm at which maximum reduction of smears is achieved for the R pixel, and the width of the opening for the B pixel is set to 540 nm at which maximum reduction of smears is achieved for the B pixel as shown in FIG. 7. With this, the amount of smear for the R pixel is reduced to 1.4, and the amount of smear for the B pixel is reduced to 0.5. The sum of the amounts of the smears for all of these colors is 2.9 (=1+1.4+0.5), resulting in 30% reduction in the amount of smears in comparison with the conventional CCD solid-state imaging device.

Here, there is concern about low sensitivity in comparison with the conventional CCD solid-state imaging device when the widths of openings in the photo-shield film 36 are varied with pixels of the colors, especially for the B pixel which has a small width of the opening. However, because blue light is originally easy to be collected in the in-layer lens 38 and has a short wavelength, blue light is less subject to shading at the opening. Thus, as shown in FIGS. 8 and 9, sensitivity to blue lowers by as little as approximately 1.5% when the width of the opening is narrowed from 620 nm to 540 nm. This variation, which is within a range of production tolerance, causes little problem for most cases. For red light, on the other hand, widening the width of the opening from 620 nm to 700 nm facilitates red light collection at the in-layer lens 38 and reduces shading at the opening, resulting in increase in sensitivity to red by as much as 6.5%. When normalizing sensitivity to green at the width of the opening of 620 nm to one, the sum of sensitivities to all of these colors is three for the conventional CCD solid-state imaging device which has the width of openings of 620 nm for all of these colors. In contrast, for the CCD solid-state imaging device 20 according to the first embodiment, the sum of sensitivities to all of these colors is 3.05 (see FIG. 9); thus the CCD solid-state imaging device 20 is superior to the conventional CCD solid-state imaging device in sensitivity.

As described above, in the CCD solid-state imaging device 20 according to the present invention, the widths of the openings in the photo-shield film 36 provided under the filter films of R, G, and B are different from one another, and the curvatures of the in-layer lenses 38 provided under the filter films of R, G, and B are different from each other. Thus, light collection at the in-layer lenses 38 and diffraction at the openings in the photo-shield film 36 can be balanced for each of the R, G, and B pixels, so that diffusion of incident light in the light-receiving units 22 of pixels of each of the colors can be reduced. As a result, a solid-state imaging device is achieved that reduces generation of unnecessary electric charges in a charge transfer unit, which causes smears, even when the size of pixels is reduced.

### Second Embodiment

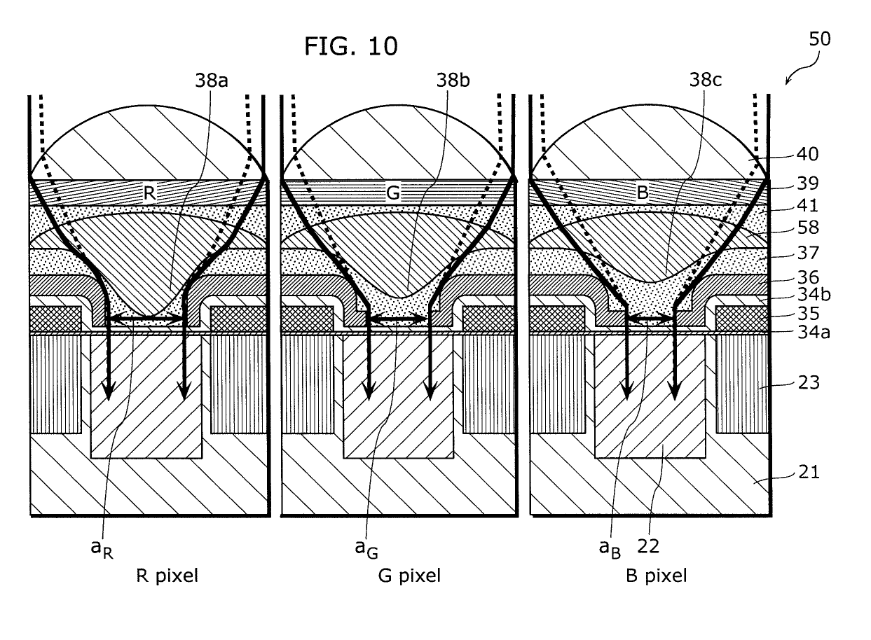

FIG. 10 is a sectional view (of approximately three pixels sectioned in a direction perpendicular to the column transfer direction) which schematically shows a structure of the CCD solid-state imaging device according to a second embodiment.

The solid-state imaging device 50 according to the second embodiment differs from the CCD solid-state imaging device 20 according to the first embodiment in that the solid-state imaging device 50 has upwardly and downwardly convex in-layer lenses 58 which are formed to have downwardly convex lens curves on the lower side thereof and upwardly convex lens curves on the upper side thereof.

In the CCD solid-state imaging device 20 according to the first embodiment, light collection to the openings in the photo-shield film 36 is performed by two lens curves of the OCL 40 placed uppermost and the downwardly convex in-layer lens 38 as shown in FIG. 1. Accordingly, in the case where the size of pixels is reduced to 2 μm×2 μm or smaller, light entering through the edge portion of the OCL 40 and passing through the edge portion of the downwardly convex in-layer lens 38 is shaded by the shoulder of the photo-shield film 36, resulting in ineffective improvement in sensitivity.

In contrast, the in-layer lens 58 in the CCD solid-state imaging device 50 according to the second embodiment is formed to be convex upward and downward. Light which has entered the CCD solid-state imaging device 50 is thus collected at three places of an OCL 40 placed uppermost, the upwardly convex lens curve and the downwardly convex lens curve of the in-layer 58. As a result, light which enters through the edge portion of the OCL 40 is led to the opening in the photo-shield film 36 without being shaded by the shoulder of the photo-shield film 36.

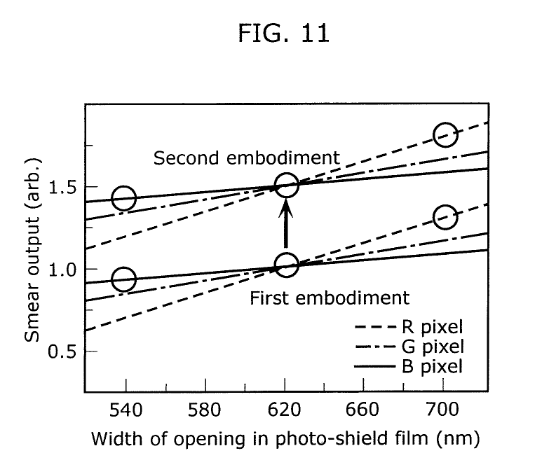

FIG. 11 shows dependency of sensitivity on widths of openings in the CCD solid-state imaging device 50 according to the second embodiment and in the CCD solid-state imaging device 20 according to the first embodiment. Circles in FIG. 11 indicate widths of openings for pixels of each of the colors in the CCD solid-state imaging devices.

In the CCD solid-state imaging device 50 according to the second embodiment, the in-layer lenses 58 formed to be convex upward and downward lead incident light which would be shaded by the photo-shield film 36 in the CCD solid-state imaging device 20 according to the first embodiment to the openings, so that sensitivity is increased by as much as approximately 10% to the pixels of the colors of R, G, and B. Improvement of sensitivity by the upwardly convex lens surface is so effective that the ratio of the amount of smear to sensitivity output, which is a smear ratio, is further improved especially when the size of pixels is reduced to 2 μm×2 μm or smaller.

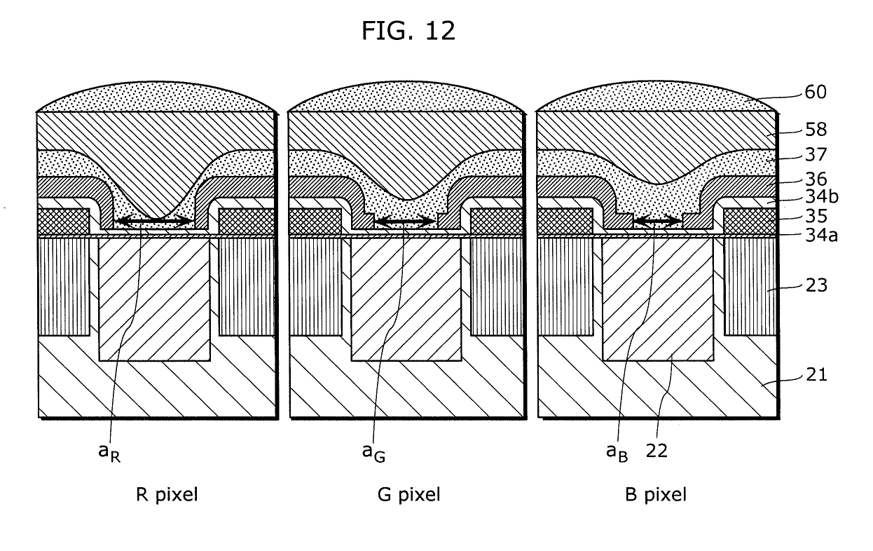

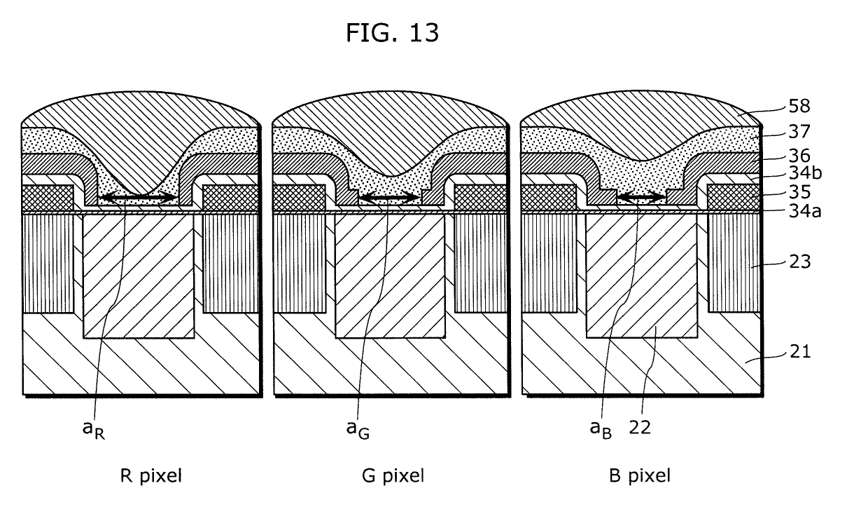

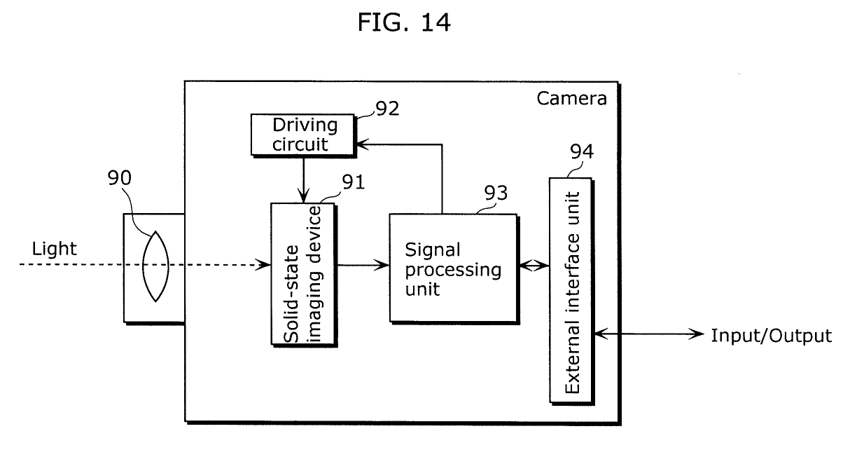

A method for manufacturing the CCD solid-state imaging device 50 which has the structure shown in FIG. 10 is hereinafter described. FIG. 12 and FIG. 13 are sectional views (of approximately three pixels sectioned in a direction perpendicular to the column transfer direction) which schematically shows the structure of the CCD solid-state imaging device 50.

This method for manufacturing the CCD solid-state imaging device 50 includes the process shown in FIG. 12 (the process for forming the light-transmissive insulating film 37 having a concave portion thereon) with the method for manufacturing a CCD solid-state imaging device according to the first embodiment. In the process shown in FIG. 12, a light-transmissive insulating film made of silicon nitride is deposited on the light-transmissive insulating layer 37 having a concave portion in the upper surface thereon using a plasma CVD method. Next, resist is applied to the surface of the silicon nitride, and then planarized. Subsequently, etchback is performed under a condition where etching selectivity ratio between the resist and the silicon nitride is one to one. This process forms an in-layer lens 58 which has a planarized surface.

Next, a resist pattern 60 which is rounded and provided with an upwardly convex lens curve is formed on the in-layer lens 58. By using this as a mask, the in-layer lens 58 is etched to form an upwardly convex curve on the surface of the in-layer lens 58 as shown in FIG. 13. Next, a planarizing film 41 is formed on the in-layer lens 58, and an OCCF 39 is formed on the planarizing film 41.

Finally, light-transmissive resin is thickly deposited on the OCCF 39 and then formed to be an OCL 40 by etching using a rounded resist pattern as a mask. This is a method for manufacturing the CCD solid-state imaging device 50 according to the second embodiment shown in FIG. 10.

In order to make the upwardly and downwardly convex in-layer lens 58 in the CCD solid-state imaging device 50 according to the second embodiment, the in-layer lens in FIG. 12 is planarized on the surface thereof and then formed through etchback using the rounded resist pattern as a mask. It is also possible to form an upward lens curve in the following process: 1. the in-layer lens 58 is planarized on the surface; 2. metal wiring such as bus line wiring is provided in a peripheral portion of the CCD solid-state imaging device 50; 3. a light-transmissive insulating film (SiN) which has the same refractive index as the light-transmissive insulating film of the in-layer lens 58 is deposited; 4. etchback is performed for the deposited light-transmissive insulating film using a rounded resist pattern which has an upwardly convex lens curve; and 5. an upwardly convex lens curve is formed on the light-transmissive insulating film deposited on the in-layer lens 58. This process allows manufacturing of the CCD solid-state imaging device 50 which has the upwardly and downwardly convex in-layer lens 58 including a downwardly convex light-transmissive insulating film and an upwardly convex light-transmissive insulating film.

As described above, the CCD solid-state imaging device 50 according to the second embodiment is achieved as a solid-state imaging device that suppresses generation of unnecessary electric charges in a charge transfer unit, which causes smears, even when the size of pixels is reduced. This is for similar reasons as those of the CCD solid-state switch 20 according to the first embodiment. Furthermore, the in-layer lens 58 which has an upwardly convex lens surface effectively leads light entering through the edge portion of the OCL 40 to the openings in the photo-shield film 36; thus the solid-state imaging device is achieved with high sensitivity.

### Third Embodiment

FIG. 14 is a block diagram of a camera according to a third embodiment.

This camera includes a lens 90, a solid-state imaging device 91 according to the first or the second embodiments, a driving circuit 92, a signal processing unit 93, and an external interface unit 94.

In the camera having this structure, a process of outputting a signal is performed in procedures described below.
(1) The light passes through the lens 90 and enters the solid-state imaging device 91.
(2) The signal processing unit 93 drives the solid-state imaging device 91 through the driving circuit 92, and then captures an output signal from the solid-state imaging device 91.
(3) The signal is processed in the signal processing unit 93 and outputted through the external interface unit 94.

As described above, in the camera according to the third embodiment, data is outputted from the solid-state imaging device which is reduced in size and improved in sensitivity and image quality. Thus, the camera according to the third embodiment is achieved as a small-size camera which provides high-quality images.

Although the solid-state imaging device and manufacturing the same according to only some exemplary embodiments of the present invention have been described in detail above, those skilled in the art will readily appreciate that many variations are possible in the exemplary embodiments without materially departing from the novel teachings and advantages of this invention. Accordingly, all such variations are intended to be included within the scope of this invention.

For example, for the CCD solid-state imaging devices according to the embodiments above, maximum reduction of smears is achieved when the widths of the openings in the photo-shield film 36 are 700 nm, 620 nm, and 540 nm for the R, G, and B pixels, respectively. These widths, however, may be varied to some extent due to height or curvature of downwardly convex portions of the in-layer lens 38 or 58 or a refractive index of the in-layer lens 38 or 58 of these pixels. Specifically, in the case where the light-transmissive film 37 is a silicon nitride film having a refractive index of 1.9, the widths of the openings in the photo-shield film 36 is preferably reduced to a width optimal for reduction of smears, approximately 79% of the original because the wavelength of light in the silicon nitride film is reduced approximately to 79% (1.5/1.9) of the wavelength in a silicon oxide film having a refractive index of 1.5. It is noted that there is a constant relationship that, in order to reduce smears for pixels of each of the colors effectively, the width of the opening in the photo-shield film 36 and the curvature of the in-layer lens 38 or 58 of a pixel which receives light of a longer wavelength are larger than the width of the opening in the photo-shield film 36 and the curvature of the in-layer lens 38 or 58 of a pixel which receives light of a shorter wavelength, respectively.

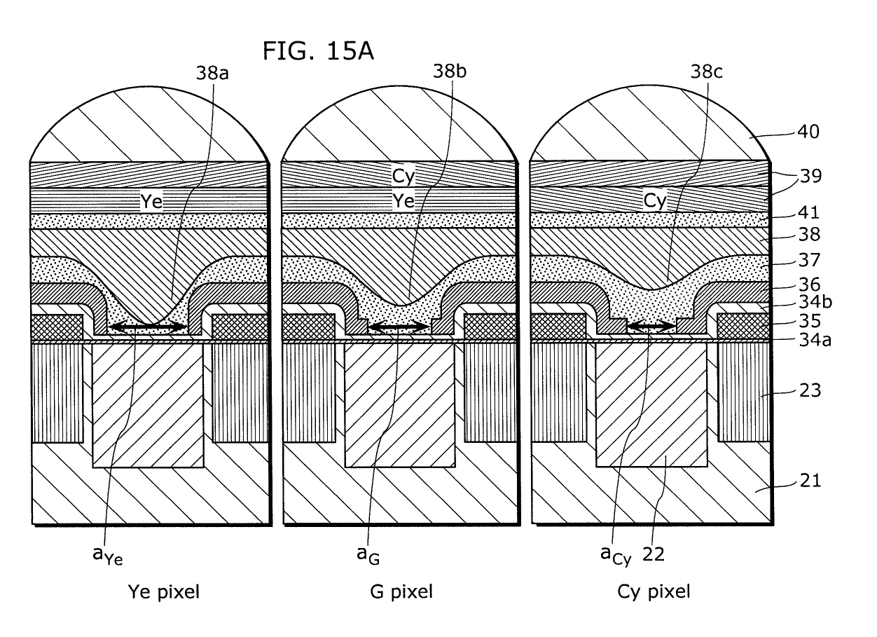

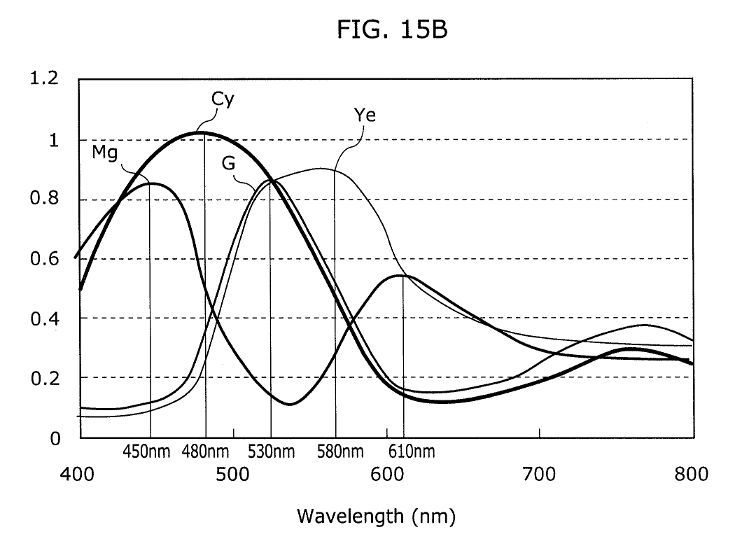

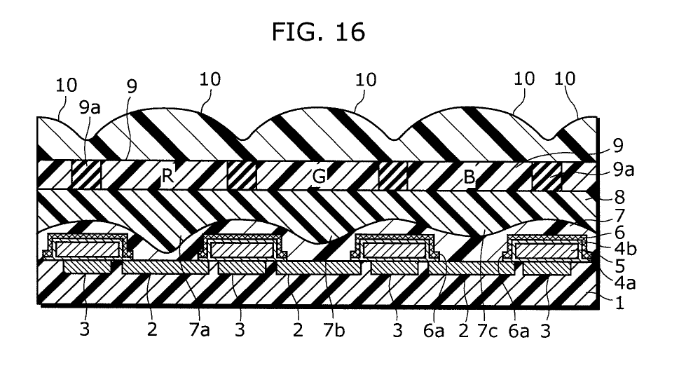

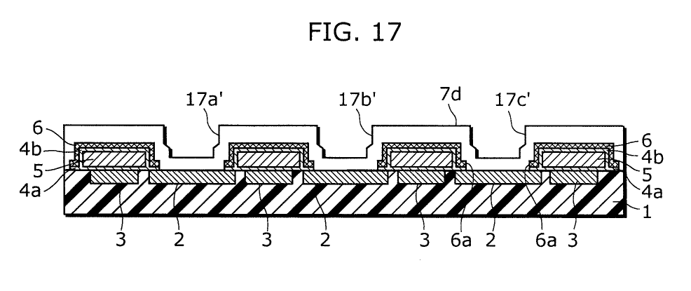

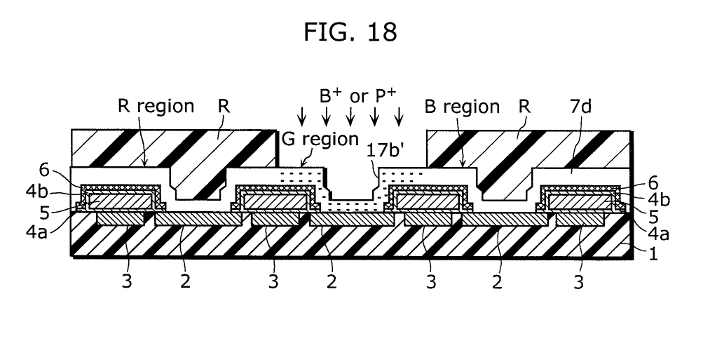

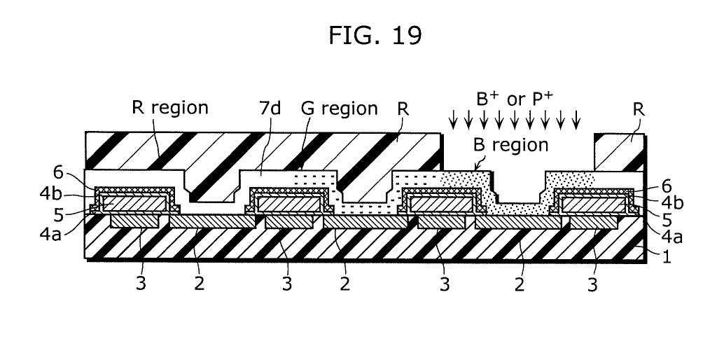

The OCCF 39 may be provided with color coding of complementary colors. FIG. 15A is a sectional view (of approximately three pixels sectioned in a direction perpendicular to the column transfer direction) which schematically shows a structure of a CCD solid-state imaging device having an OCCF 39 of complementary colors. FIG. 15B shows a spectral sensitivity characteristic of the CCD solid-state imaging device shown in FIG. 15A. The OCCF 39 of the CCD solid-state imaging device shown in FIG. 15A has a Ye filter film which transmits light in a wavelength region of yellow (Ye), an Mg filter film which transmits light in a wavelength region of magenta (Mg), and a Cy filter film which transmits light in a wavelength region of cyan (Cy). A G filter film is formed by overlaying the Ye filter film and the Cy filter film. A width of an opening in a photo-shield film 36 corresponding to the Ye filter film is equal to or larger than a wavelength in a light-transmissive insulting film 37 of yellow light which is transmitted by the Ye filter film. A width of an opening in a photo-shield film 36 corresponding to the G filter film is equal to or larger than a wavelength in a light-transmissive insulting film 37 of green light which is transmitted by the G filter film. A width of an opening in a photo-shield film 36 corresponding to the Cy filter film is equal to or larger than a wavelength in a light-transmissive insulting film 37 of cyan light which is transmitted by the Cy filter film. The width of the opening in the photo-shield film 36 corresponding to the Ye filter film is larger than the width of the opening in the photo-shield film 36 corresponding to the G filter film. The width of the opening in the photo-shield film 36 corresponding to the G filter film is larger than the width of the opening in the photo-shield film 36 corresponding to the Cy filter film. The width of the opening in the photo-shield film 36 corresponding to the Mg filter film is equal to the width of the opening in the photo-shield film 36 corresponding to the G filter film.

In the case where the light-transmissive insulating film 37 is made of BPSG, the light-transmissive insulating film 37 has a refractive index of approximately 1.5; thus the wavelength of the yellow light in the light-transmissive insulating film 37 is a value obtained by dividing the value of the wavelength (approximately 530 to 610 nm) of yellow light in vacuum by 1.5. Similarly, the wavelength of the green light in the light-transmissive insulating film 37 is a value obtained by dividing the value of the wavelength (approximately 480 to 580 nm) of green light in vacuum by 1.5. The wavelength of the cyan light in the light-transmissive insulating film 37 is a value obtained by dividing the value of the wavelength (approximately 450 to 530 nm) of cyan light in vacuum by 1.5. Accordingly, to fulfill the conditions of the widths of the opening described above, the opening of the pixel Ye has a width (a_{Ye}) of, for example, 670 nm, the opening of the G pixel has a width (a_{G}) of, for example, 620 nm, and the opening of the pixel Cy has a width (a_{Cy}) of, for example, 570 nm.

### INDUSTRIAL APPLICABILITY

The present invention is applicable to a solid-state imaging device and a method for manufacturing the same, especially to a solid-state imaging device having a small size and a large number of pixels and a method for manufacturing the same.

What is claimed is:

1. A solid-state imaging device, comprising:
light-receiving units formed on a surface in a substrate;
a photo-shield film formed above the substrate and having an opening above each of said light-receiving units;
a light-transmissive insulating film formed above said photo-shield film and in the openings in said photo-shield film;
in-layer lenses each of which is downwardly convex, made of a material having a refractive index different from a refractive index of said light-transmissive insulating film, and formed above said light-transmissive insulating film;
a color filter formed above said in-layer lenses and including a first filter and a second filter which are positioned above different light-receiving units among said light-receiving units, each of the first filter and the second filter transmitting light, and a wavelength of the light which the first filter transmits and a wavelength of the light which the second filter transmits being different from each other; and
an on-chip lens formed above each of said in-layer lenses,
wherein a width of the opening provided in said photo-shield film and under the first filter is different from a width of the opening provided in said photo-shield film and under the second filter, and a curvature of said in-layer lenses provided under the first filter is different from a curvature of said in-layer lenses provided under the second filter.

2. The solid-state imaging device according to claim 1,
wherein each of said in-layer lenses further has a lens curve which is upwardly convex.

3. The solid-state imaging device according to claim 2,
wherein the width of the opening provided in said photo-shield film corresponding to a specific one of the first and second filters is equal to or larger than a wavelength of light in said light-transmissive insulating film, the light being transmitted by the specific one of the first and second filters.

4. The solid-state imaging device according to claim 3,
wherein said color filter is an array of a red filter which transmits red light, a green filter which transmits green light, and a blue filter which transmits blue light,
the width of the opening provided in said photo-shield film and corresponding to the red filter is larger than the width of the opening provided in said photo-shield film and corresponding to the green filter,
the width of the opening provided in said photo-shield film and corresponding to the green filter is larger than the width of the opening provided in said photo-shield film and corresponding to the blue filter,
the curvature of said in-layer lenses corresponding to the red filter is larger than the curvature of said in-layer lenses corresponding to the green filter, and
the curvature of said in-layer lenses corresponding to the green filter is larger than the curvature of said in-layer lenses corresponding to the blue filter.

5. The solid-state imaging device according to claim 4,
wherein the width of the opening provided in said photo-shield film and corresponding to the red filter is equal to or larger than a wavelength of red light in said light-transmissive insulating film,
the width of the opening provided in said photo-shield film and corresponding to the green filter is equal to or larger than a wavelength of green light in said light-transmissive insulating film, and
the width of the opening provided in said photo-shield film and corresponding to the blue filter is equal to or larger than a wavelength of blue light in said light-transmissive insulating film.

6. The solid-state imaging device according to claim 3,
wherein said color filter is an array of a yellow filter which transmits yellow light, a green filter which transmits green light, and a cyan filter which transmits cyan light,
the width of the opening provided in said photo-shield film and corresponding to the yellow filter is larger than the width of the opening in said photo-shield film and corresponding to the green filter,
the width of the opening provided in said photo-shield film and corresponding to the green filter is larger than the width of the opening provided in said photo-shield film and corresponding to the cyan filter,
the curvature of said in-layer lenses corresponding to the yellow filter is larger than the curvature of said in-layer lenses corresponding to the green filter, and
the curvature of said in-layer lenses corresponding to the green filter is larger than the curvature of said in-layer lenses corresponding to the cyan filter.

7. The solid-state imaging device according to claim 6,
the width of the opening provided in said photo-shield film and corresponding to the yellow filter is equal to or larger than a wavelength of yellow light in said light-transmissive insulating film,
the width of the opening provided in said photo-shield film and corresponding to the green filter is equal to or larger than a wavelength of green light in said light-transmissive insulating film, and
the width of the opening provided in said photo-shield film and corresponding to the cyan filter is equal to or larger than a wavelength of cyan light in said light-transmissive insulating film.

8. The solid-state imaging device according to claim 1,
wherein the width of the opening provided in said photo-shield film corresponding to a specific one of the first and second filters is equal to or larger than a wavelength of light in said light-transmissive insulating film, the light being transmitted by the specific one of the first and second filters.

9. The solid-state imaging device according to claim 1,
wherein said color filter is an array of a red filter which transmits red light, a green filter which transmits green light, and a blue filter which transmits blue light,
the width of the opening provided in said photo-shield film and corresponding to the red filter is larger than the width of the opening provided in said photo-shield film and corresponding to the green filter,
the width of the opening provided in said photo-shield film and corresponding to the green filter is larger than the width of the opening provided in said photo-shield film and corresponding to the blue filter,
the curvature of said in-layer lenses corresponding to the red filter is larger than the curvature of said in-layer lenses corresponding to the green filter,
the curvature of said in-layer lenses corresponding to the green filter is larger than the curvature of said in-layer lenses corresponding to the blue filter.

10. The solid-state imaging device according to claim 1,
wherein said color filter is an array of a yellow filter which transmits yellow light, a green filter which transmits green light, and a cyan filter which transmits cyan light,
the width of the opening provided in said photo-shield film and corresponding to the yellow filter is larger than the width of the opening in said photo-shield film and corresponding to the green filter,
the width of the opening provided in said photo-shield film and corresponding to the green filter is larger than the width of the opening provided in said photo-shield film and corresponding to the cyan filter,
the curvature of said in-layer lenses corresponding to the yellow filter is larger than the curvature of said in-layer lenses corresponding to the green filter, and
the curvature of said in-layer lenses corresponding to the green filter is larger than the curvature of said in-layer lenses corresponding to the cyan filter.

11. A method for manufacturing a solid-state imaging device, said method comprising:
forming a photo-shield film above a substrate on which light-receiving units are formed;
forming openings having different widths in positions above the light-receiving units in the photo-shield film;
forming a first light-transmissive insulating film above the photo-shield film and in the openings in the photo-shield film;
forming above the first light-transmissive insulating film a first in-layer lens which is downwardly convex and made of a second light-transmissive insulating film having a refractive index different from a refractive index of the first light-transmissive insulating film; and
forming a color filter and on-chip lenses above the in-layer lenses.

12. The method for manufacturing a solid-state imaging device according to claim 11, said method further comprising
forming second in-layer lenses by (i) forming on the second light-transmissive insulating film resist patterns which have upwardly convex lens curves and then (ii) etching the second light-transmissive insulating film using the resist patterns as masks so as to form upwardly convex lenses on the in-layer lenses.

13. The method for manufacturing a solid-state imaging device according to claim 11, said method further comprising:
forming second in-layer lenses by (i) forming a third light-transmissive insulating film above the second light-transmissive insulating film, (ii) forming on the third light-transmissive insulating film resist patterns which have upwardly convex lens curves, and then (iii) etching the third light-transmissive insulating film using the resist patterns as masks so as to form upwardly convex lenses made of the third light-transmissive insulating film.
